(19) United States
(12) Patent Application Publication
(10) Pub. No.: US 2019/0051857 A1
(43) Pub. Date: Feb. 14, 2019

(54) ORGANIC LIGHT-EMITTING DIODE ENCAPSULATION STRUCTURE, METHOD FOR FABRICATING THE SAME, AND ORGANIC LIGHT-EMITTING DIODE

(71) Applicant: BOE Technology Group Co., Ltd., Beijing (CN)

(72) Inventors: Pan XU, Beijing (CN); YI-CHENG LIN, Beijing (CN); Quanhu LI, Beijing (CN)

(21) Appl. No.: 15/982,544

(22) Filed: May 17, 2018

(30) Foreign Application Priority Data
Aug. 10, 2017 (CN) 201710681963.6

(51) Int. Cl. H01L 51/52; H01L 27/32; H01L 51/56

(52) U.S. Cl. CPC H01L 51/524; H01L 51/5221; H01L 51/56; H01L 27/322; H01L 27/3246

(57) ABSTRACT

This disclosure discloses an organic light-emitting diode encapsulation structure, a method for fabricating the same, and an organic light-emitting diode, and the organic light-emitting diode encapsulation structure includes: a cover plate; an array substrate arranged opposite to the cover plate; a spacing layer arranged on at least one of the surface of the edge of the array substrate facing the cover plate, and the surface of the edge of the cover plate facing the array substrate; and wherein the cover plate and the array substrate are bonded to each other through frame sealing glue affixed on the spacing layer into a box; and the surface of the spacing layer bonded through the frame sealing glue is structured in a concave-convex pattern.

This application claims priority of Chinese Patent Application No. 201710681963.6, filed with the Chinese Patent Office on Aug. 10, 2017, which is hereby incorporated by reference in its entirety.

### FIELD

This disclosure relates to the field of display technologies, and particularly to an organic light-emitting diode encapsulation structure, a method for fabricating the same, and an organic light-emitting diode.

### BACKGROUND

As the industry of Organic Light-Emitting Diodes (OLEDs) has become matured gradually, there is a desirably higher and higher quality of OLED. An emission layer of OLED may be greatly destroyed by humidity and oxygen, and a light emitting material at the emission layer in contact with humidity and oxygen may be degenerated so that the light emitting material can not operate normally. Accordingly in the industry of OLEDs, an OLED is encapsulated to thereby prevent humidity and oxygen from entering the OLED. Encapsulation processes generally include DAM (annular encapsulation) and Face (face encapsulation) for different types of products. As their names reply, in the DAM process, the product is coated with glue on the peripheral thereof, and encapsulated with a cover plate into a box; and in the Face process, the entire face of the product is coated with glue, and then encapsulated with a cover plate into a box. Both of the encapsulation processes are performed in vacuum so that humidity and oxygen is absent from the box, and prevented from entering the product from the outside.

### SUMMARY

An embodiment of this disclosure provides an organic light-emitting diode encapsulation structure including: a cover plate; an array substrate arranged opposite to the cover plate; a spacing layer arranged on at least one of a surface of the edge of the array substrate facing the cover plate and a surface of the edge of the cover plate facing the array substrate; and wherein the cover plate and the array substrate are bonded to each other through frame sealing glue affixed on the spacing layer into a box; and a surface of the spacing layer bonded through the frame sealing glue is structured in a concave-convex pattern.

An embodiment of this disclosure provides an organic light-emitting diode including the organic light-emitting diode encapsulation structure above according to the embodiment of this disclosure.

An embodiment of this disclosure further provides a method for fabricating an organic light-emitting diode encapsulation structure, the method including the steps of: preparing an array substrate; arranging a cover plate opposite to the array substrate; forming a spacing layer on at least one of the surface of the edge of the array substrate facing the cover plate, and the surface of the edge of the cover plate facing the array substrate; etching the spacing layer to form concave-convex structures on the surface of the spacing layer; arranging frame sealing glue between the array substrate and the cover plate so that the frame sealing glue is affixed on the spacing layer; and aligning the array substrate with the cover plate into a box.

### BRIEF DESCRIPTION OF THE DRAWINGS

FIG. 1 is a schematic structural diagram of an organic light-emitting diode including an organic light-emitting diode encapsulation structure in the related art.

FIG. 2 is a schematic diagram of the organic light-emitting diode including the organic light-emitting diode encapsulation structure in the related art in a top view.

FIG. 3 is a schematic structural diagram of an organic light-emitting diode including an organic light-emitting diode encapsulation structure according to an embodiment of this disclosure.

FIG. 4 is a schematic diagram of the organic light-emitting diode including the organic light-emitting diode encapsulation structure according to the embodiment of this disclosure in a top view.

FIG. 5 is a schematic structural diagram of an organic light-emitting diode including another organic light-emitting diode encapsulation structure according to an embodiment of this disclosure.

### DETAILED DESCRIPTION OF THE EMBODIMENTS

This disclosure will be described below in further details with reference to the drawings and the embodiments thereof. As can be appreciated, the embodiments to be described below are merely intended to illustrate this disclosure, but not to limit this disclosure thereto. It shall be further noted that for the sake of a convenient description, only a part of structural components according to this disclosure are illustrated in the drawings.

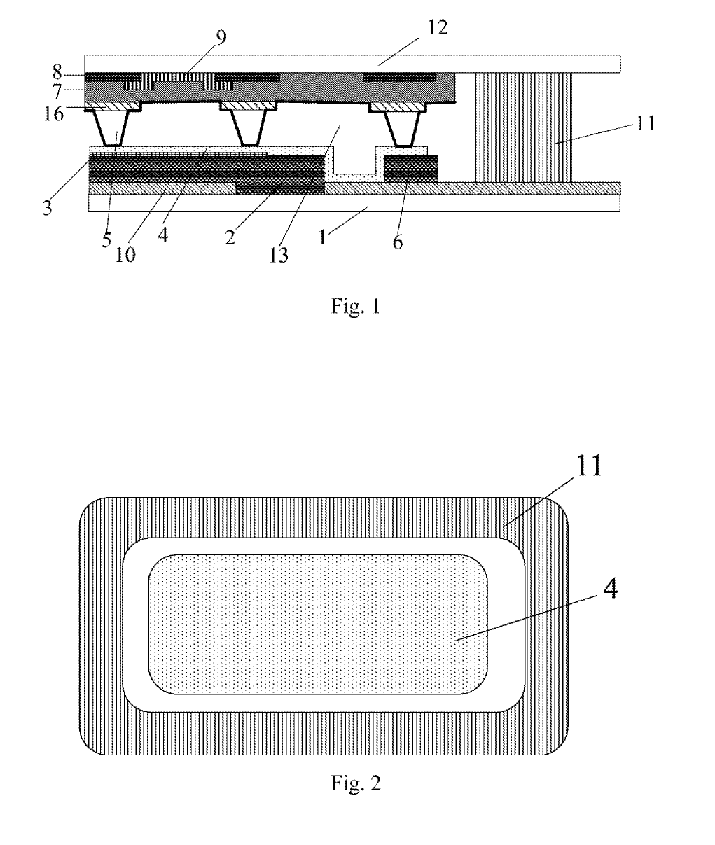

As illustrated in FIG. 1, an organic light-emitting diode in the related art includes: an array substrate 1; an oxide layer 10 and an active layer 2 arranged on the array substrate 1; a Cover Layer (CL) 3 and a cathode area 4 arranged on the active layer 2; a pixel definition layer 6 arranged on the oxide layer 10; a cover plate 12 arranged opposite to the array substrate 1; a black matrix 8 and a color filter layer 9 arranged on the face of the cover plate 12 opposite to the array substrate 1; an Organic Cover (OC) 7 covering the black matrix 8 and the color filter layer 9; an auxiliary layer (AUX) 16 arranged on the organic cover 7; a spacer 5 arranged between the auxiliary layer 16 and the cathode area 4; and a filler 13 filled between the array substrate 1 and the array substrate 12, all of which are conventional structural components of the organic light-emitting diode. An organic light-emitting diode encapsulation structure in the related art includes the edge of the array substrate 1, and the edge of the cover plate 12 among the conventional structural components above, and frame sealing glue 11, surrounding the conventional structural components above, arranged between the edge of the array substrate 1, and the edge of the cover plate 12, and FIG. 2 illustrates a top view of the organic light-emitting diode including the organic light-emitting diode encapsulation structure, where the cathode area 4 including the conventional structural components above is surrounded by the frame sealing glue 11.

In this encapsulation structure, there is poor contact tightness between the frame sealing glue 11 and the array substrate 1, and between the frame sealing glue 11 and the cover plate 12. Humidity and oxygen may enter through a contact interface between the frame sealing glue and the substrate due to the contact tightness between them, and a pathway of the entering humidity and oxygen, so it is typical to improve the tightness of encapsulation by increasing the width of the frame sealing glue, and extending the pathway of the entering humidity and oxygen, but it may be difficult to achieve a good effect in this way.

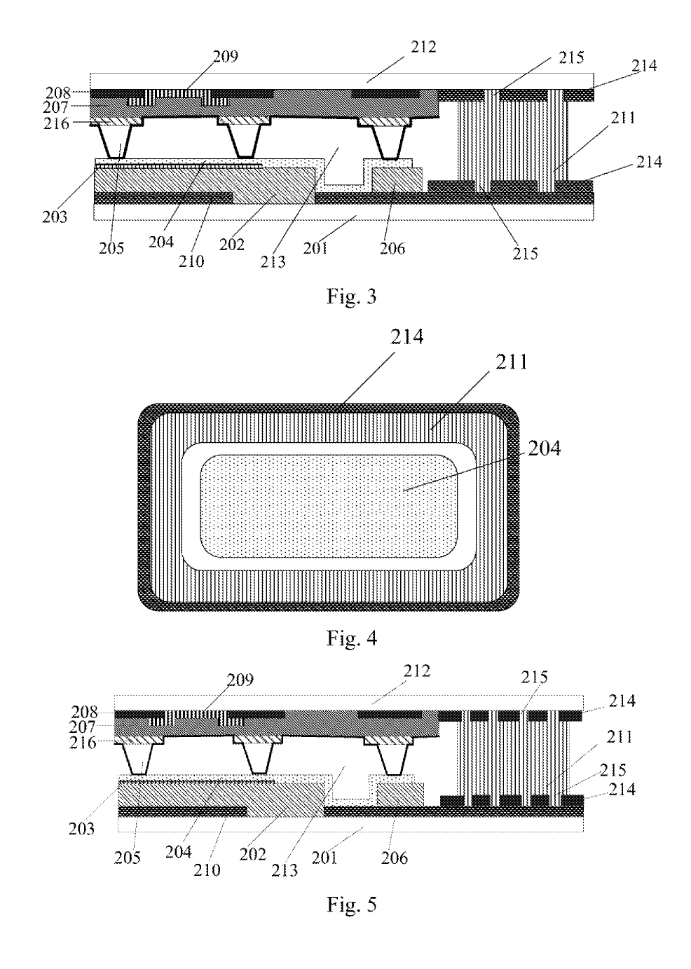

Some embodiments of this disclosure provide an organic light-emitting diode encapsulation structure, and FIG. 3 illustrates a schematic structural diagram thereof.

The organic light-emitting diode encapsulation structure includes an array substrate 201, a cover plate 212 arranged opposite to the array substrate 201, and a spacing layer 214 arranged on the edge of the array substrate 201. The cover plate and the array substrate are bonded into a box through frame sealing glue 211, where the frame sealing glue 211 on the array substrate is affixed on the spacing layer 214, and the surface of the spacing layer 214 is structured in a concave-convex pattern; and FIG. 3 illustrates an embodiment in which there are a plurality of grooves 215 at the spacing layer 214 by way of an example, but the surface of the spacing layer 214 can alternatively be structured in another concave-convex shape, e.g., a strip or grid pattern, or an inconsecutive cross-strip pattern.

In the example as illustrated in FIG. 3, the frame sealing glue 211 is filled into the grooves 215 at the spacing layer 214 on the array substrate 201 to thereby improve the bonding between the frame sealing glue and the array substrate 201 so as to enhance the firmness of encapsulation.

Furthermore a spacing layer 214 is also arranged on the surface of the edge of the cover plate 212 opposite to the edge of the array substrate 201. The surface of the spacing layer 214 is structured in a concave-convex pattern, and FIG. 4 illustrates a top view thereof, where the cathode area 204 is surrounded by the frame sealing glue 211, and the frame sealing glue 211 is surrounded by the spacing layer 214 and bonded to the spacing layer 214 to thereby improve the firmness of encapsulation.

FIG. 5 also illustrates in an embodiment there are a plurality of grooves 215 at the spacing layer 214 on the cover plate by way of an example, where the surface of the spacing layer 214 can also be shaped in a strip or grid pattern, or an inconsecutive cross-strip pattern. The pattern on the surface of the spacing layer on the cover plate 212 may or may not be the same as the pattern on the surface of the spacing layer on the array substrate.

Frame sealing glue 211 is filled into the grooves 215 at the spacing layer on the cover plate 212 to thereby improve the bonding between the frame sealing glue 211 and the array substrate 212 so as to enhance the firmness of encapsulation.

The spacing layer 214 can be an oxynitride film layer or can be a metal film layer. Appropriate frame sealing glue can be selected according to bonding capacities of different frame sealing glue to different materials, and when the spacing layer 214 is an oxynitride film layer or a metal film layer, the spacing layer 214 is made of a different material. Table 1 depicts a test result of bonding capacities of different frame sealing glue to different materials.

TABLE 1
A test result of bonding capacities of different
frame sealing glue to different materials

| | DAM glue 1 (with a | DAM glue 2 (with a |
|---|---|---|
| | primary component | primary component |
| | of oxygen resin) | of oxygen resin) |
| Shearing strength (MPa) | 25.8 | 20 |
| Glass/glass | | |
| 0.5 μm\hat{ }2*80 μmt | | |
| Shearing strength (MPa) | 26.3 | 19 |
| SiNx&SiOx/SiNx&SiOx | | |
| 0.5 μm\hat{ }2*80 μmt | | |
| Shearing strength (MPa) | 24 | 20.2 |
| Metal (aluminum)/metal | | |
| (aluminum) | | |
| 0.5 μm\hat{ }2*80 μmt | | |
| Shearing strength (MPa) | 24.2 | 21 |
| Metal | | |
| (copper)/metal(copper) | | |
| 0.5 μm\hat{ }2*80 μmt | | |

As depicted in Table 1, there is the best bonding between the DAM glue 1 and SiNx&SiOx, so when the DAM glue 1 is used as the frame sealing glue, SiNx&SiOx is selected as a material of the spacing layer 214, and then the grooves or other concave-convex structures are formed at the spacing layer 214 to thereby further improve the bonding between the frame sealing glue and the spacing layer.

There is the best bonding between the DAM glue 2 and copper, so when the DAM glue 2 is used as the frame sealing glue, a copper film layer is selected as a material of the spacing layer 214, and then the grooves or other concave-convex structures are formed at the spacing layer 214 to thereby further improve the bonding between the frame sealing glue and the spacing layer.

In the case that the spacing layer 214 is an oxynitride film layer, the spacing layer 214 can be formed in the same process as oxynitride film layers to be formed on the cover plate 212 and the array substrate 201.

In the case that the spacing layer 214 is a metal film layer, a copper film layer can be used as the spacing layer. FIG. 3 illustrates a schematic diagram of the organic light-emitting diode encapsulation structure when the spacing layer 214 is a copper film layer.

With the organic light-emitting diode encapsulation structure according to this embodiment, the firmness of encapsulation can be improved to make it more difficult for humidity and oxygen to enter the product, without increasing the width of the frame sealing glue.

An embodiment of this disclosure further provides an organic light-emitting diode including: an array substrate 201; an oxide layer 210 and an active layer 202 arranged on the array substrate 201; a Cover Layer (CL) 203 and a cathode area 204 arranged on the active layer 202; a pixel definition layer 206 arranged on the oxide layer 210; a cover plate 212 arranged opposite to the array substrate 201; a black matrix 208 and a color filter layer 209 arranged on the face of the cover plate 212 opposite to the array substrate 201; an Organic Cover (OC) 207 covering the black matrix 208 and the color filter layer 209; an auxiliary layer (AUX) 216 arranged on the organic cover 207; a spacer 205 arranged between the auxiliary layer 216 and the cathode area 204; and a filler 213 filled between the array substrate 201 and the array substrate 212. The organic light-emitting diode further includes the organic light-emitting diode encapsulation structure according to any one of the embodiments above. Reference can be made to the organic light-emitting diode encapsulation structure above, so a repeated description thereof will be omitted here.

Some embodiment of this disclosure provides a method for fabricating an organic light-emitting diode encapsulation structure, where the method is used to fabricate the organic light-emitting diode encapsulation structure according to any one of the embodiments above.

In the case that the organic light-emitting diode encapsulation structure includes the spacing layer made of oxynitride, the method includes the following steps.

The array substrate is prepared, and thereafter the oxynitride film layer is formed on the surface of the array substrate facing the cover plate; and the oxynitride film layer is exposed and etched to form the concave-convex structures on the surface of the oxynitride film layer, e.g., the grooves 215 as illustrated in FIG. 3. Optionally the oxynitride film layer can be formed on the surface of the edge of the array substrate facing the cover plate.

The cover plate is arranged opposite to the array substrate, and thereafter the oxynitride film layer is formed on at least the surface of the cover plate facing the array substrate; and the oxynitride film layer is exposed and etched to form the concave-convex structures on the surface of the oxynitride film layer, e.g., the grooves 215 as illustrated in FIG. 3. Optionally the oxynitride film layer can be formed on the surface of the edge of the cover plate facing the array substrate.

The frame sealing glue is arranged between the oxynitride film layer of the array substrate, and the oxynitride film layer of the cover plate so that the frame sealing glue is affixed on the oxynitride film layer, and filled into the concave-convex structures on the oxynitride film layer to thereby improve the firmness of encapsulation.

The array substrate is aligned with the cover plate into a box. In an example here, both the oxynitride film layers on the array substrate and the cover plate are formed with the concave-convex structures (e.g., the grooves 215 as illustrated in FIG. 3), but the concave-convex structures can be formed on the oxynitride film layer of only one of the array substrate and the cover plate without departing from the scope of this disclosure.

In the case that the organic light-emitting diode encapsulation structure includes the spacing layer which is a metal film layer, the method includes the following steps.

The array substrate is prepared, and thereafter the metal film layer is formed on the surface of the array substrate facing the cover plate; and the metal film layer is exposed and etched to form the concave-convex structures on the surface of the metal film layer, e.g., the grooves 215 as illustrated in FIG. 3. Optionally the metal film layer can be formed on the surface of the edge of the array substrate facing the cover plate.

The cover plate is arranged opposite to the array substrate, and thereafter the metal film layer is formed on at least the surface of the cover plate facing the array substrate; and the metal film layer is exposed and etched to form the concave-convex structures on the surface of the metal film layer, e.g., the grooves 215 as illustrated in FIG. 3. Optionally the metal film layer can be formed on the surface of the edge of the cover plate facing the array substrate.

The frame sealing glue is arranged between the metal film layer of the array substrate, and the metal film layer of the cover plate so that the frame sealing glue is affixed on the metal film layer, and filled into the concave-convex structures on the oxynitride film layer to thereby improve the firmness of encapsulation.

The array substrate is aligned with the cover plate into a box. In an example here, both the metal film layers on the array substrate and the cover plate are formed with the concave-convex structures (e.g., the grooves 215 as illustrated in FIG. 3), but the concave-convex structures can be formed on the metal film layer of only one of the array substrate and the cover plate without departing from the scope of this disclosure.

Those skilled in the art shall appreciate that this disclosure will not be limited to the particular embodiments described above, and those skilled in the art can make various obvious variations, rearrangements, and alternatives thereto without departing from the scope of this disclosure. Accordingly although this disclosure has been described in details in connection with the embodiments thereof above, this disclosure will not be limited thereto, but more other equivalent embodiments will be possible without departing from the sprit of this disclosure, and the scope of this disclosure shall be as defined in the appended claims.

1. An organic light-emitting diode encapsulation structure, comprising:
a cover plate;
an array substrate arranged opposite to the cover plate;
a spacing layer arranged on at least one of a surface of an edge of the array substrate facing the cover plate and a surface of an edge of the cover plate facing the array substrate; and
wherein the cover plate and the array substrate are bonded to each other through frame sealing glue affixed on the spacing layer into a box; and a surface of the spacing layer bonded through the frame sealing glue is structured in a concave-convex pattern.

2. The organic light-emitting diode encapsulation structure according to claim 1, wherein there are a plurality of grooves on the surface of the spacing layer bonded through the frame sealing glue.

3. The organic light-emitting diode encapsulation structure according to claim 1, wherein the spacing layer is an oxynitride film layer.

4. The organic light-emitting diode encapsulation structure according to claim 3, wherein the spacing layer is formed integral to an oxynitride film layer on at least of the array substrate and the cover plate.

5. The organic light-emitting diode encapsulation structure according to claim 1, wherein the spacing layer is a metal film layer.

6. The organic light-emitting diode encapsulation structure according to claim 1, wherein the surface of the spacing layer bonded through the frame sealing glue comprises at least one of a strip pattern, a grid pattern and an inconsecutive cross strip pattern.

7. The organic light-emitting diode encapsulation structure according to claim 1, wherein in a case that the spacing layer is arranged on both of the surface of the edge of the array substrate facing the cover plate and the surface of the edge of the cover plate facing the array substrate, a shape of the surface, of the spacing layer arranged on the surface of the edge of the array substrate facing the cover plate, bonded through the frame sealing glue is same as a shape of the surface, of the spacing layer arranged on the surface of the edge of the cover plate facing the array substrate, bonded through the frame sealing glue.

8. The organic light-emitting diode encapsulation structure according to claim 1, wherein in a case that the spacing layer is arranged on both of the surface of the edge of the array substrate facing the cover plate and the surface of the edge of the cover plate facing the array substrate, a shape of the surface, of the spacing layer arranged on the surface of the edge of the array substrate facing the cover plate, bonded through the frame sealing glue is different from a shape of the surface, of the spacing layer arranged on the surface of the edge of the cover plate facing the array substrate, bonded through the frame sealing glue.

9. An organic light-emitting diode, comprising the organic light-emitting diode encapsulation structure according to claim 1.

10. The organic light-emitting diode according to claim 9, wherein there are a plurality of grooves on the surface of the spacing layer bonded through the frame sealing glue.

11. The organic light-emitting diode according to claim 9, wherein the spacing layer is an oxynitride film layer.

12. The organic light-emitting diode according to claim 11, wherein the spacing layer is formed integral to an oxynitride film layer on at least of the array substrate and the cover plate.

13. The organic light-emitting diode according to claim 9, wherein the spacing layer is a metal film layer.

14. The organic light-emitting diode according to claim 9, wherein the surface of the spacing layer bonded through the frame sealing glue comprises at least one of a strip pattern, a grid pattern and an inconsecutive cross-strip pattern.

15. The organic light-emitting diode according to claim 9, wherein in a case that the spacing layer is arranged on both of the surface of the edge of the array substrate facing the cover plate, and the surface of the edge of the cover plate facing the array substrate, a shape of the surface, of the spacing layer arranged on the surface of the edge of the array substrate facing the cover plate, bonded through the frame sealing glue is same as a shape of the surface, of the spacing layer arranged on the surface of the edge of the cover plate facing the array substrate, bonded through the frame sealing glue.

16. The organic light-emitting diode according to claim 9, wherein in a case that the spacing layer is arranged on both of the surface of the edge of the array substrate facing the cover plate, and the surface of the edge of the cover plate facing the array substrate, a shape of the surface, of the spacing layer arranged on the surface of the edge of the array substrate facing the cover plate, bonded through the frame sealing glue is different from a shape of the surface, of the spacing layer arranged on the surface of the edge of the cover plate facing the array substrate, bonded through the frame sealing glue.

17. A method for fabricating an organic light-emitting diode encapsulation structure, the method comprising steps of:
preparing an array substrate;
arranging a cover plate opposite to the array substrate;
forming a spacing layer on at least one of a surface of an edge of the array substrate facing the cover plate, and a surface of an edge of the cover plate facing the array substrate;
processing the spacing layer to form concave-convex structures on a surface of the spacing layer;
arranging frame sealing glue between the array substrate and the cover plate so that the frame sealing glue is affixed on the spacing layer; and
aligning the array substrate with the cover plate into a box.
